(19) United States
(12) Patent Application Publication
(10) Pub. No.: US 2016/0079418 A1
(43) Pub. Date: Mar. 17, 2016

(54) SEMICONDUCTOR DEVICE AND METHOD FOR MANUFACTURING THE SAME

(71) Applicant: Kabushiki Kaisha Toshiba, Minato-ku (JP)

(72) Inventor: Atsushi MURAKOSHI, Yokkaichi (JP)

(73) Assignee: Kabushiki Kaisha Toshiba, Minato-ku (JP)

(21) Appl. No.: 14/613,830

(22) Filed: Feb. 4, 2015

Related U.S. Application Data
(60) Provisional application No. 62/048,838, filed on Sep. 11, 2014.

(51) Int. Cl. H01L 29/78; H01L 29/167; H01L 29/08; H01L 29/66; H01L 21/266; H01L 29/423; H01L 21/265; H01L 21/02

(52) U.S. Cl. CPC H01L 29/7833; H01L 21/26513; H01L 29/167; H01L 21/02238; H01L 29/66545; H01L 21/266; H01L 29/42364; H01L 29/6659; H01L 21/02164; H01L 29/0847; H01L 21/02255

(57) ABSTRACT

According to one embodiment, a method is disclosed for manufacturing a semiconductor device. The method can include an ion implantation process of performing ion implantation of an ion species including at least one type of atom of boron, antimony, arsenic, phosphorus, or indium into a semiconductor region at low temperature, and an electrode formation process of forming a source region and a drain region at two mutually-separated locations on the semiconductor region and forming an electrode in a region directly above the semiconductor region between the source region and the drain regions of the two locations with an insulating film interposed between the electrode and the semiconductor region.

### CROSS-REFERENCE TO RELATED APPLICATIONS

This application is based upon and claims the benefit of priority from U.S. Provisional Patent Application 62/048,838, filed on Sep. 11, 2014; the entire contents of which are incorporated herein by reference.

### FIELD

Embodiments described herein relate generally to a semiconductor device and a method for manufacturing the same.

### BACKGROUND

In the manufacturing processes of semiconductor devices, there are many cases where ion implantation is performed to introduce impurities to the semiconductor substrate. However, the impurity introduction into the semiconductor substrate by normal ion implantation methods may damage the crystal structure in the interior of the semiconductor substrate and cause the flatness to degrade at the front surface of the semiconductor substrate. There is a possibility that such effects of the ion implantation on the semiconductor substrate may cause the electrical characteristics of the semiconductor device such as the current driving capability, etc., to decrease.

### BRIEF DESCRIPTION OF THE DRAWINGS

FIG. 1 is a cross-sectional view showing a semiconductor device according to an embodiment;

FIGS. 2A to 6C are cross-sectional views of processes, showing a method for manufacturing the semiconductor device according to the embodiment;

FIG. 7 is a schematic view showing a state of a silicon substrate when an ion implantation of the silicon substrate having a temperature of −135° C. or less is performed;

FIG. 8A is a graph showing a dependence of an on-current on the length of a gate electrode, where a horizontal axis is a length L (μm) of the gate electrode shown in FIG. 1, and a vertical axis is the on-current (μA/μm); and FIG. 8B is a graph showing a dependence of a threshold voltage on the length of the gate electrode, where a horizontal axis is the length L (μm) of the gate electrode shown in FIG. 1, and a vertical axis is the threshold voltage (V);

FIG. 9 is a figure showing results of measurements by AFM of an upper surface of a p-type impurity layer of the semiconductor device for a second comparative example and a second example;

FIG. 10 is a figure showing results of measurements by AFM of the upper surface of the p-type impurity layer of the semiconductor device for a third comparative example, a fourth comparative example, and a third example;

FIG. 11A and FIG. 11B are graphs showing a charge trap amount of interface states, where a horizontal axis is a injected charge amount (C/cm²), and a vertical axis is a change amount (mV) of a gate voltage characteristics, FIG. 11A shows in case of temperature of room-temperature, FIG. 11B shows in case of temperature of −150° C.; and

FIG. 12 is a graph showing hysteretic characteristics before and after a constant voltage stress, where a horizontal axis is an electrical oxide film thickness (nm), and a vertical axis is a change amount (mV/cm) of an electric field strength.

### DETAILED DESCRIPTION

In general, according to one embodiment, a method is disclosed for manufacturing a semiconductor device. The method can include an ion implantation process of performing ion implantation of an ion species including at least one type of atom of boron, antimony, arsenic, phosphorus, or indium into a semiconductor region at low temperature, and an electrode formation process of forming a source region and a drain region at two mutually-separated locations on the semiconductor region and forming an electrode in a region directly above the semiconductor region between the source region and the drain region of the two locations with an insulating film interposed between the electrode and the semiconductor region.

In the embodiments, it is possible to implement the embodiments in the case where P-type and N-type are interchanged.

Embodiments of the invention will now be described with reference to the drawings.

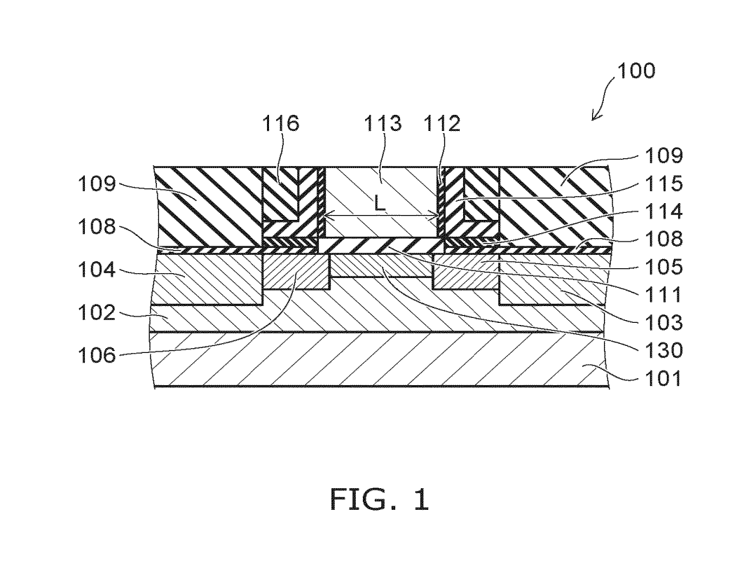

First, a semiconductor device according to the embodiment will be described. FIG. 1 is a cross-sectional view showing the semiconductor device according to the embodiment.

As shown in FIG. 1, a silicon substrate (a semiconductor region) 101 is provided in the semiconductor device 100 according to the embodiment. A surface channel layer (a channel region) 102 is formed in the upper layer portion of the silicon substrate 101. Source/drain regions 103 and 104 are formed in the upper layer portion of the surface channel layer 102 to be separated from each other. N-type impurity extension layers 105 and 106 are provided between the source/drain regions 103 and 104 to be separated from each other. The n-type impurity extension layer 105 contacts the source/drain region 103; and the n-type impurity extension layer 106 contacts the source/drain region 104. A p-type channel layer 130 is formed between the n-type impurity extension layer 105 and the n-type impurity extension layer 106.

A gate insulator film 108 is provided on the upper surfaces of the source/drain region 103, the n-type impurity extension layer 105, the source/drain region 104, and the n-type impurity extension layer 106. Also, a gate insulator film 111 is provided in the region directly above the p-type channel layer 130. The gate insulator film 111 is thicker than the gate insulator film 108. An insulating film 114 is provided on a portion of the gate insulator film 108 on the gate insulator film 111 side.

A barrier metal film 112 and a gate electrode 113 are provided on the gate insulator film 111. The side surface of the gate electrode 113 is covered with the barrier metal film 112. An insulating film 115 and an insulating film 116 are provided on the side surface of the barrier metal film 112 and on the upper surface of the insulating film 114. The insulating film 115 covers the lower surface of the insulating film 116 and the side surface of the insulating film 116 on the gate electrode 113 side. An inter-layer insulating film 109 is provided on the gate insulator film 108 in the regions directly above the source/drain regions 103 and 104. The upper surface of the inter-layer insulating film 109, the side surface of the end portion of the insulating film 115, the side surface of the two end portions of the barrier metal film 112, and the upper surface of the gate electrode are at the same height.

For example, in the case where the silicon substrate 101 is formed of an n-type semiconductor and the portions corresponding to the n-type impurity extension layers 105 and 106 are provided as p-type impurity extension layers into which a p-type dopant is ion-implanted, an n-type channel layer into which an n-type dopant is ion-implanted is provided in the portion corresponding to the p-type channel layer 130.

A method for manufacturing the semiconductor device according to the embodiment will now be described.

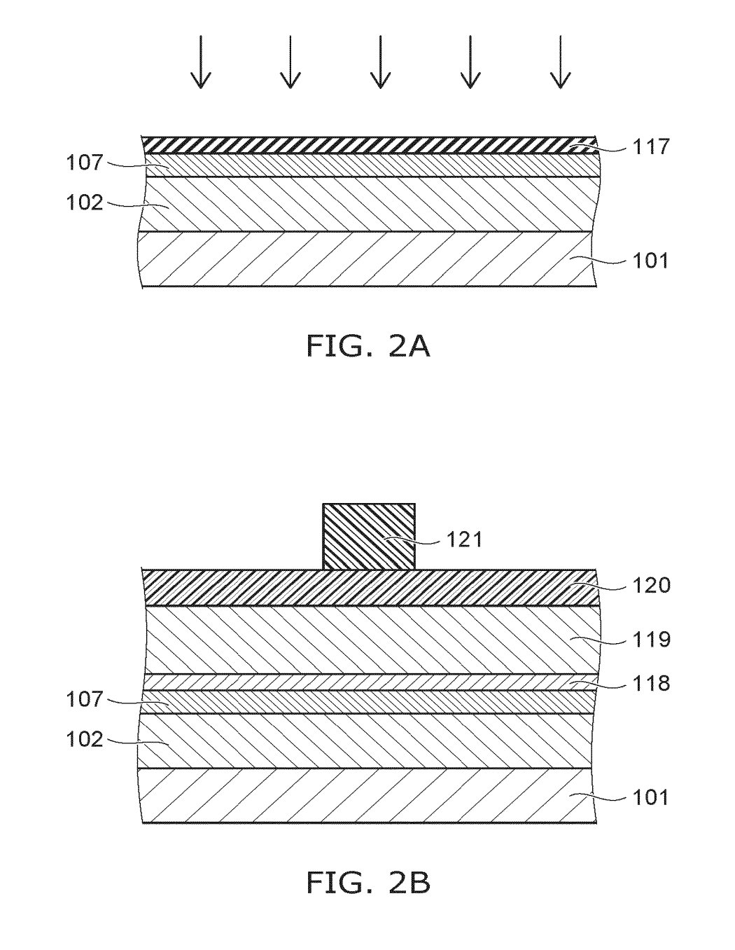

FIGS. 2A to 6C are cross-sectional views of processes, showing the method for manufacturing the semiconductor device according to the embodiment.

First, as shown in FIG. 2A, the silicon substrate 101 is prepared. Then, a buffer oxide film 117 is formed by oxidizing the upper layer portion of the silicon substrate 101 by thermal oxidation. For example, a silicon oxide film of 10 nm is formed as the buffer oxide film 117 by heating in an oxygen atmosphere to a temperature of 900° C.

Then, the entire silicon substrate 101 and the structural body formed on and in the interior of the silicon substrate 101 (hereinbelow, generally called the “substrate”) are cooled to a temperature of −135° C. or less by indirect cooling using liquid helium as a coolant. Ion implantation is performed from above the buffer oxide film 117 while the entire substrate is maintained at −135° C. or less. For example, ion implantation of boron (B) is performed at the conditions of an acceleration energy of 260 keV and a dose of 5×10¹³ cm⁻² and at the conditions of an acceleration energy of 130 keV and a dose of 1×10¹³ cm⁻² in the state in which the entire substrate is cooled to −150° C. Thereby, a p-type impurity layer 107 is formed under the buffer oxide film 117.

Then, ion implantation of boron is performed from above the buffer oxide film 117 at the conditions of an acceleration energy of 10 keV and a dose of 4×10¹² cm⁻². Thereby, the surface channel layer 102 is formed. Subsequently, activation and crystal recovery of the ion implantation layer is realized by performing thermal annealing maintained for 10 seconds at a temperature of 1035° C.

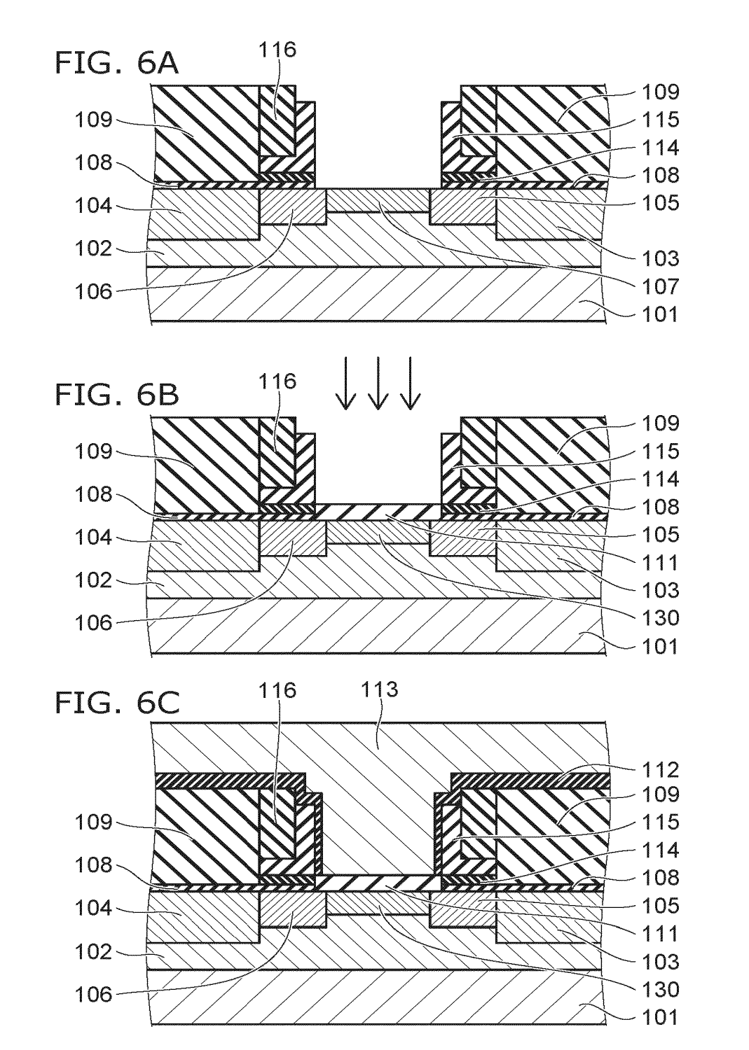

Here, it is also possible to form the surface channel layer 102 by performing the ion implantation and the thermal annealing in a state in which the channel layer shown in FIG. 6A below is exposed.

Then, as shown in FIG. 2B, after peeling the buffer oxide film 117 by wet etching using DHF (Dilute Hydrofluoric Acid), a silicon oxide film having a film thickness of, for example, 6 nm is formed as a gate insulator film 118 by performing oxidation at 750° C. using a WVG (Water Vapor Generator).

Then, a dummy gate electrode film 119 having a film thickness of, for example, 100 nm is formed by depositing amorphous silicon doped with phosphorus (P) by CVD (Chemical Vapor Deposition).

Then, a mask material 120 is formed on the dummy gate electrode film 119. Then, a resist material is coated onto the mask material 120; exposing is performed by irradiating light such as ultraviolet light, etc.; and subsequently, developing is performed. Thereby, a resist pattern 121 is formed on the mask material 120.

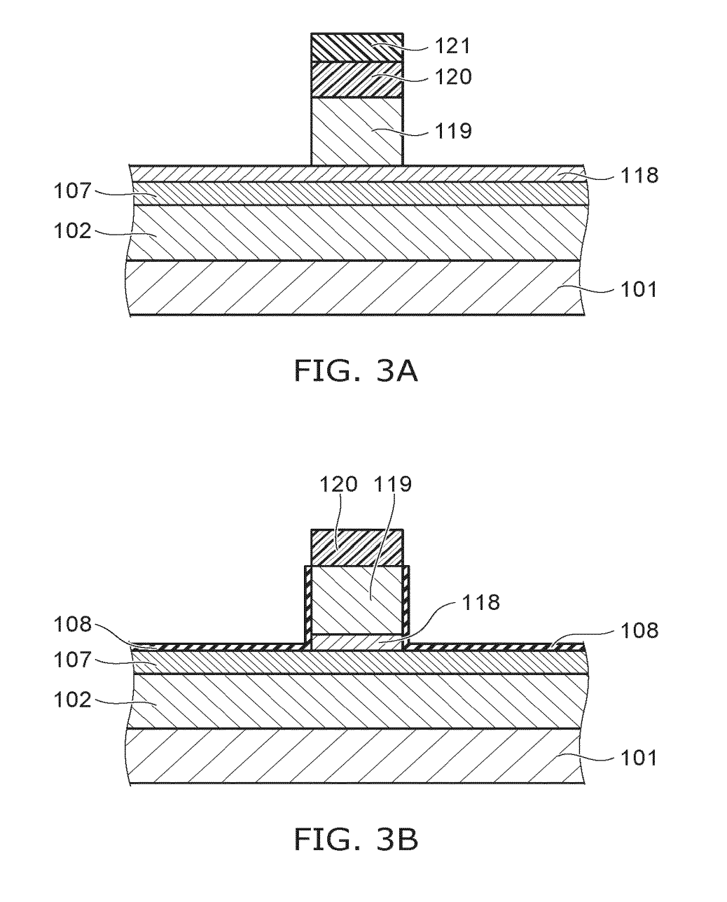

Then, as shown in FIG. 3A, the mask material 120 and the dummy gate electrode film 119 are selectively removed by performing RIE (Reactive Ion Etching) using the resist pattern 121 as a mask. Thereby, the upper surface of the portion of the gate insulator film 118 not masked by the resist pattern 121 is exposed.

Then, as shown in FIG. 3B, the resist pattern 121 is peeled. Then, the exposed portion of the upper surface of the gate insulator film 118 is selectively removed by wet etching using DHF. Thereby, the upper surface of the p-type impurity layer 107 of the layer under the gate insulator film 118 removed by the wet etching is exposed. Subsequently, the gate insulator film 108 is formed at the exposed portion of the upper surface of the p-type impurity layer 107, the side surface of the gate insulator film 118, and the side surface of the dummy gate electrode film 119 by performing RTO (Rapid Thermal Oxidation) processing. The film thickness of the gate insulator film 108 is, for example, 2 nm.

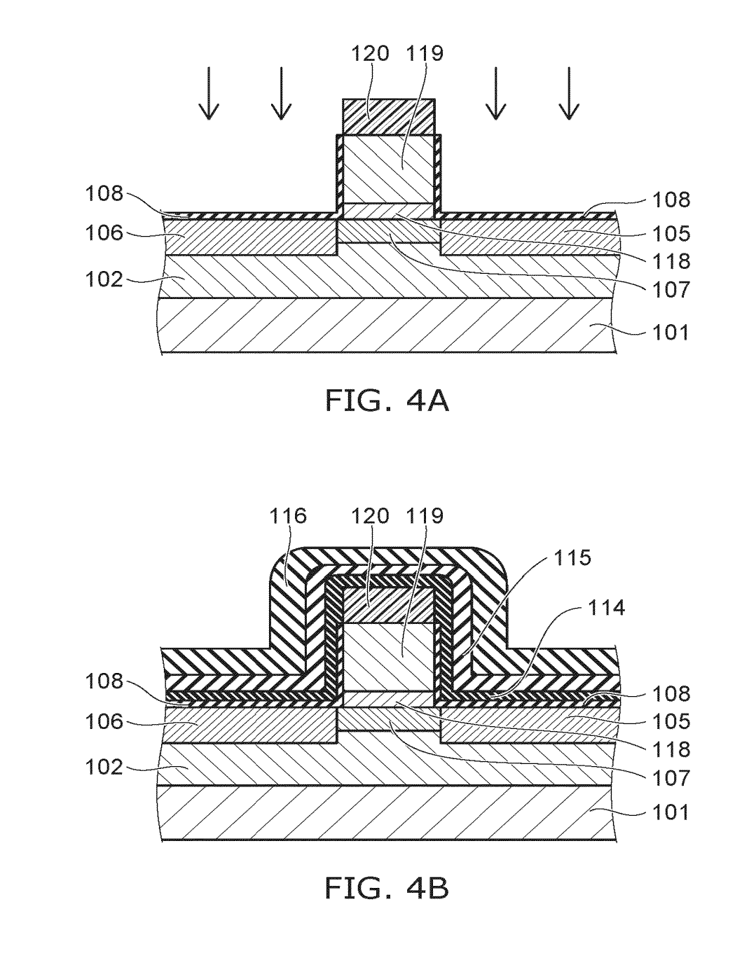

Then, as shown in FIG. 4A, ion implantation of the p-type impurity layer 107 and the upper layer portion of the surface channel layer 102 is performed using the mask material 120, the dummy gate electrode film 119, and one end portion of the gate insulator film 108 formed on the side surface of the dummy gate electrode film 119 as a mask. At this time, the entire substrate is cooled to −135° C. or less. Thereby, the n-type impurity extension layers 105 and 106 are formed in the p-type impurity layer 107 and the upper layer portion of the surface channel layer 102 that are unmasked portions. The conditions of the ion implantation are set to be, for example, a temperature of the substrate of −150° C., an impurity of arsenic, an acceleration energy of 10 keV, and a dose of 2×10¹⁴ cm⁻².

Then, as shown in FIG. 4B, the insulating film 114 that includes silicon oxide is formed to have a film thickness of, for example, 10 nm on the entire surface of the substrate as an offset spacer film by CVD using TEOS (Tetra Ethyl Ortho Silicate) as a source material. Then, the insulating film 115 that includes silicon nitride is formed on the insulating film 114 by CVD. Subsequently, the insulating film 116 that includes silicon oxide is formed as a spacer film on the insulating film 115 by CVD using TEOS as a source material.

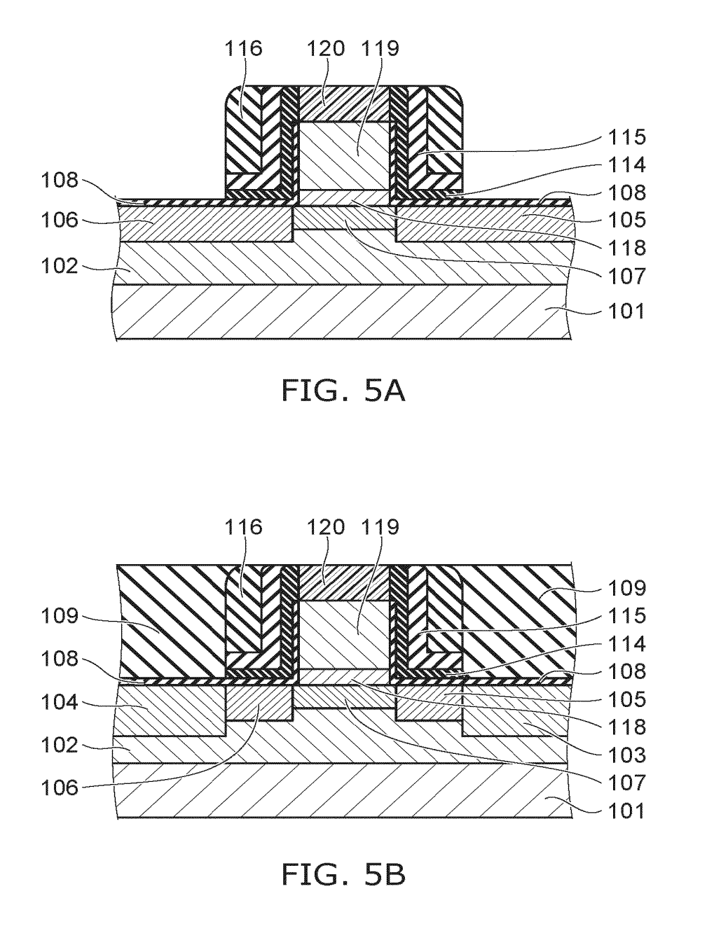

Then, as shown in FIG. 5A, the insulating films 114, 115, and 116 are caused to remain on the side surface of the stacked body made of the gate insulator film 118, the dummy gate electrode film 119, and the mask material 120 and are removed from the other regions by performing etch-back of the entire surface. Thereby, the upper surface of the mask material 120 and the upper surface of one portion of the gate insulator film 108 are exposed.

Then, as shown in FIG. 5B, the entire substrate is cooled to −135° C. or less by indirect cooling using liquid helium as a coolant. Then, ion implantation is performed while maintaining the entire substrate at −135° C. or less. For example, ion implantation of arsenic (As) is performed from above the silicon substrate 101 by setting the acceleration energy to 20 keV and the dose to 1×10¹⁵ cm⁻² in a state in which the entire substrate is cooled to −150° C. Subsequently, activation and crystal recovery of the ion implantation layer is performed by RTA (Rapid Thermal Annealing). For example, the RTA is maintained for 30 seconds at a temperature of 900° C. Thereby, the source/drain regions 103 and 104 are formed in the portions of the n-type impurity extension layers 105 and 106 and the upper layer portion of the surface channel layer 102 region directly under the n-type impurity extension layers 105 and 106 that are not covered with the insulating films 114, 115, and 116.

Then, the inter-layer insulating film 109 is formed in a region on the gate insulator film 108 that includes the regions directly above the source/drain regions 103 and 104. The inter-layer insulating film 109 is formed by, for example, depositing an insulating material such as silicon oxide, etc., on the substrate by CVD and performing planarization by CMP (Chemical Mechanical Polishing).

Then, as shown in FIG. 6A, the mask material 120 is removed by wet etching using hot phosphoric acid. Then, the dummy gate electrode film 119 is removed by wet etching using a mixed acid solution including hydrofluoric acid, nitric acid, and acetic acid. Subsequently, the gate insulator film 118 and the one portion of the gate insulator film 108 contacting the side surfaces of the dummy gate electrode film 119 and the gate insulator film 118 are removed by wet etching using DHF. At this time, the gate insulator film 108 remains on the upper surfaces of the source/drain regions 103 and 104 and the n-type impurity extension layers 105 and 106.

Here, it is also possible to form the surface channel layer 102 shown in FIG. 2A by performing ion implantation and thermal annealing in a state in which the channel layer is exposed.

In the case of such a surface channel layer post-formation, because the thermal budget performed when passing through the film formation processes can be reduced, the control of the surface concentration becomes easy; and the controllability of the threshold voltage improves.

Then, as shown in FIG. 6B, the gate insulator film 111 is formed on the p-type impurity layer 107 and on the surface channel layer 102 by, for example, thermal oxidation by WVG processing. Subsequently, the entire substrate is cooled to −135° C. or less, e.g., −150° C. Then, boron is ion-implanted into the p-type impurity layer 107. Thereby, the p-type impurity layer 107 becomes the p-type channel layer 130.

After the ion implantation, the gate insulator film 111 may be removed; and the gate insulator film 111 may be formed again. The gate insulator film 111 is, for example, a silicon oxide film having a film thickness of 5 nm. At this time, plasma nitriding of the upper layer portion of the gate insulator film 111 that is formed may be performed.

Then, as shown in FIG. 6C, the barrier metal film 112 is formed on the entire substrate by CVD. Then, the gate electrode 113 is formed on the barrier metal film 112 by CVD.

Then, as shown in FIG. 1, the barrier metal film 112 and the gate electrode 113 that are on the side surface of the one end portion of the insulating film 115, on the insulating film 116, and on the inter-layer insulating film 109 are removed by performing planarization by CMP. At this time, the barrier metal film 112 and the gate electrode 113 remain on the gate insulator film 111.

Thus, the semiconductor device according to the embodiment is manufactured.

Effects of the embodiment will now be described.

In the embodiment, the entire silicon substrate 101 is cooled to −135° C. or less when performing the ion implantation of the silicon substrate 101.

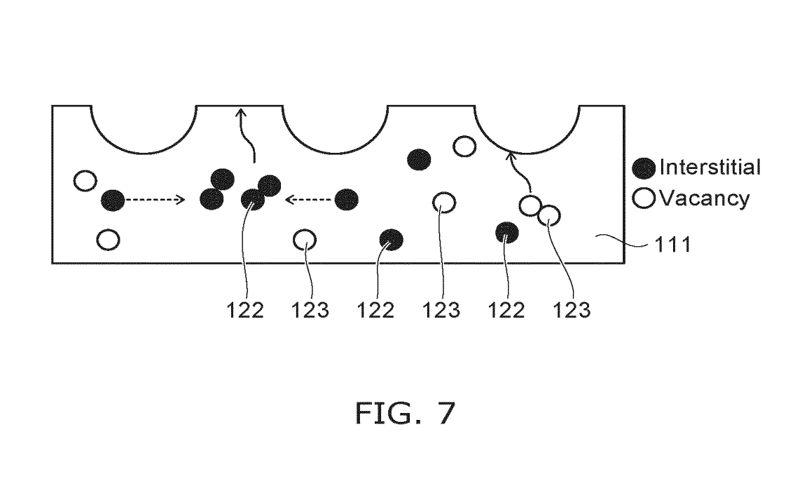

FIG. 7 is a schematic view showing the state of the substrate when the ion implantation of the silicon substrate having a temperature of −135° C. or less is performed. The buffer oxide film 117 (referring to FIG. 2A) is not shown in FIG. 7.

As shown in FIG. 7, interstitial atoms 122 and vacancies 123 occur when ion implantation of the silicon substrate 101 is performed. The interstitial atoms 122 and the vacancies 123 cluster at room temperature due to movement of the interstitial atoms 122 and the vacancies 123. Thereby, localized protrusions caused by the clusters of the interstitial atoms 122 and localized dent caused by the clusters of the vacancies 123 are made in the upper surface of the silicon substrate 101. On the other hand, in the silicon substrate 101 cooled to −135° C. or less, the movement of the interstitial atoms 122 substantially is not suppressed, but the movement of the vacancies 123 is suppressed. Thereby, the clustering of the vacancies 123 is suppressed. Accordingly, the formation of the localized dent in the upper surface of the silicon substrate 101 is suppressed.

In other words, although the localized protrusions are formed in the upper surface of the silicon substrate 101 at temperatures of −135° C. or less, the formation of the localized dent is suppressed; and therefore, compared to the case where the ion implantation is performed at a higher temperature, the upper surface of the region of the silicon substrate 101 where the ion implantation is performed is smooth. Accordingly, the processes of planarization, etc., after the ion implantation can be omitted.

Also, compared to other regions, much of the current flows through the substrate surface of the p-type channel layer 130 in the region directly under the gate electrode 113 (referring to FIG. 1). Therefore, the improvement of the current characteristics can be expected to be more for when the ion implantation for forming the p-type channel layer 130 is performed at −135° C. or less than for the case where the ion implantation of the regions other than the p-type channel layer 130 is performed at −135° C. or less. Also, in the case where the gate electrode 113 degrades after forming the p-type channel layer 130, the decrease of the current characteristics due to the degradation of the gate electrode 113 can be avoided by re-forming the gate electrode 113.

In the semiconductor device 100, in the case where the flatness is lost at the upper surface of the region where the ion implantation of the silicon substrate 101 is performed, mismatch of the crystal structure occurs at the interface between the surface and the gate insulator films 108 and 111. At this time, interface states are formed at the interface where the mismatch occurs. Thereby, electron traps and hole traps occur; and there is a possibility that the conduction current may decrease. Also, the electron traps and the hole traps existing at the interface function as scattering centers and cause a decrease of the mobility of the carriers in the p-type channel layer 130.

Conversely, if the flatness is improved at the upper surface of the region where the ion implantation of the silicon substrate 101 is performed, phenomena such as those described above can be suppressed.

Also, normally, when ion implantation is performed at room temperature, the formation of an amorphous layer and recrystallization are caused at the substrate upper surface due to the thermal energy generated when the incident ions impact the substrate. On the other hand, when the ion implantation is performed at a low temperature, the heat that is generated when the ion beam impacts the substrate is absorbed; and the recrystallization is suppressed. Thereby, the flatness of the front surface of the substrate after the ion implantation can be improved.

Thereby, in the semiconductor device 100 according to the embodiment, the decrease of the conduction current and the decrease of the mobility of the carriers are suppressed; and the electrical characteristics improve.

Although boron and arsenic are used as the ion species in the ion implantation of the embodiment, the ion species may be phosphorus (P), antimony (Sb) indium (In), etc.; and ion implantation of a molecular form such as, for example, BF₂ or B₁₀H₁₄ may be performed.

Effects of the embodiment will now be described with reference to test examples.

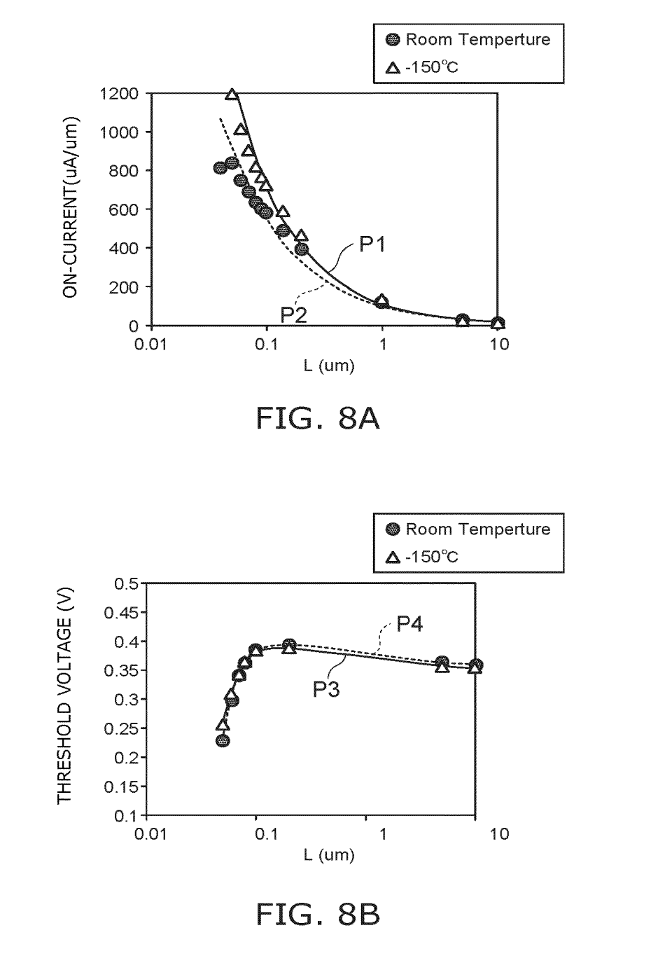

FIG. 8A is a graph showing the dependence of the on-current on the length of the gate electrode, where the horizontal axis is a length L (μm) of the gate electrode shown in FIG. 1, and the vertical axis is the on-current (μA/μm); and FIG. 8B is a graph showing the dependence of the threshold voltage on the length of the gate electrode, where the horizontal axis is the length L (μm) of the gate electrode shown in FIG. 1, and the vertical axis is the threshold voltage (V).

First, as a first example, a semiconductor device was manufactured by the method described in the embodiment described above. In the semiconductor device of the first example, the temperature of the silicon substrate 101 was cooled to about −150° C. in the ion implantation.

Also, as a first comparative example, a semiconductor device was manufactured by performing the ion implantation at room temperature and performing the other manufacturing processes similarly to those of the embodiment. At this time, the temperature of the substrate in the ion implantation was set to about 60° C.

Then, the on-current per channel length of the first example and the first comparative example were evaluated.

As shown in FIG. 8A when measurement data P1 of the first example and measurement data P2 of the first comparative example are compared, the increase amount of the on-current becomes large as the length L of the gate electrode 113 shortens for the first example. The difference of the increase amount of the on-current is observed markedly in the case where the length is 1 μm or less. Accordingly, in the case of cooling the silicon substrate 101 to about −150° C. when performing the ion implantation, it could be markedly confirmed that the on-current per channel length increases for a channel length of 1 μm or less. Thereby, this shows that the current driving capability of the semiconductor device is improved by cooling the silicon substrate 101 to about −150° C. when performing the ion implantation in the processes of making the semiconductor device.

Also, as shown in FIG. 8B, for the relationship between the threshold voltage and the length L of the gate electrode, a pronounced difference was not observed between measurement data P3 of the first example and measurement data P4 of the first comparative example. That is, it was confirmed that the increase of the on-current described above was not caused by differences between the activation concentration and the lateral diffusion length of the source/drain regions 103 and 104 and the n-type impurity extension layers 105 and 106.

Then, the flatness of the upper surface where the ion implantation is performed was evaluated for different ion implantation doses for the process of forming the p-type channel layer 130 in the upper layer portion of the silicon substrate 101.

The evaluation was performed using the semiconductor device of the first comparative example and the semiconductor device of the first example described above. The surface area of these semiconductor devices was set to be 10 μm².

First, the gate electrode 113 and the barrier metal film 112 were removed by SPM (Sulfuric acid Peroxide Mixture) processing for the semiconductor devices manufactured with different ion implantation doses. Then, the gate insulator film 111 was removed by DHF processing. A region of the upper surface of the p-type channel layer 130 exposed by the DHP processing having a surface area of 2 μm² was measured using an AFM (Atomic Force Microscope). The ion species was boron (B+); and the acceleration energy was set to 10 keV.

The ion implantation dose, the surface average of roughness height (Ra), and the maximum roughness height (Rmax) for the first example and the first comparative example are shown in Table 1.

TABLE 1

| | | 1 × 10¹³ (cm⁻²) | 1 × 10¹⁴ (cm⁻²) | 1 × 10¹⁵ (cm⁻²) |
|---|---|---|---|---|
| First | Ra | 0.172 nm | 0.191 nm | 0.218 nm |
| comparative | Rmax | 2.162 nm | 2.951 nm | 2.616 nm |
| example | | | | |
| First | Ra | 0.163 nm | 0.164 nm | 0.177 nm |
| example | Rmax | 1.779 nm | 1.776 nm | 1.933 nm |

In the first comparative example as shown in Table 1, the values of the surface average of roughness height (Ra) and the maximum roughness height (Rmax) both became large as the ion implantation dose increased. The surface average of roughness height (Ra) was 0.218 nm and the maximum roughness height (Rmax) was 2.616 nm when the ion implantation dose was its highest of 1×10¹⁵ cm⁻².

On the other hand, in the first example, even in the case where the ion implantation dose was its highest of 1×10¹⁵ cm², the values of the surface average of roughness height (Ra) and the maximum roughness height (Rmax) were about the same as or less than the surface average of roughness height (Ra) and the maximum roughness height (Rmax) of the first comparative example for the lowest ion implantation dose of 1×10¹³ cm⁻².

Also, in the case of the first example, it is estimated that the flatness of the front surface was improved when the heat generated by the ion beam impacting the silicon substrate 101 was absorbed and the recrystallization was suppressed by cooling the silicon substrate 101.

Then, to more markedly observe the effects in the case where the silicon substrate is cooled when performing the ion implantation, semiconductor devices of a second comparative example and a second example were made by performing ion implantation of arsenic, which has a greater mass and atomic size than boron, instead of boron into the region corresponding to the p-type channel layer 130. At this time, the acceleration energy was set to 10 keV; and the dose was set to 2×10¹⁵ cm⁻². Other than arsenic being ion-implanted into the portion corresponding to the p-type channel layer 130 instead of boron, the configuration of the semiconductor device of the second comparative example is similar to that of the semiconductor device of the first comparative example. Also, other than arsenic being ion-implanted into the portion corresponding to the p-type channel layer 130 instead of boron, the configuration of the semiconductor device of the second example is similar to that of the semiconductor device of the first example.

Then, the gate electrode 113 and the barrier metal film 112 were removed by SPM processing and the gate insulator film 111 was removed by DHF processing for the semiconductor devices. A region of the upper surface of the p-type channel layer 130 thus exposed having a surface area of 2 μm² was measured by AFM.

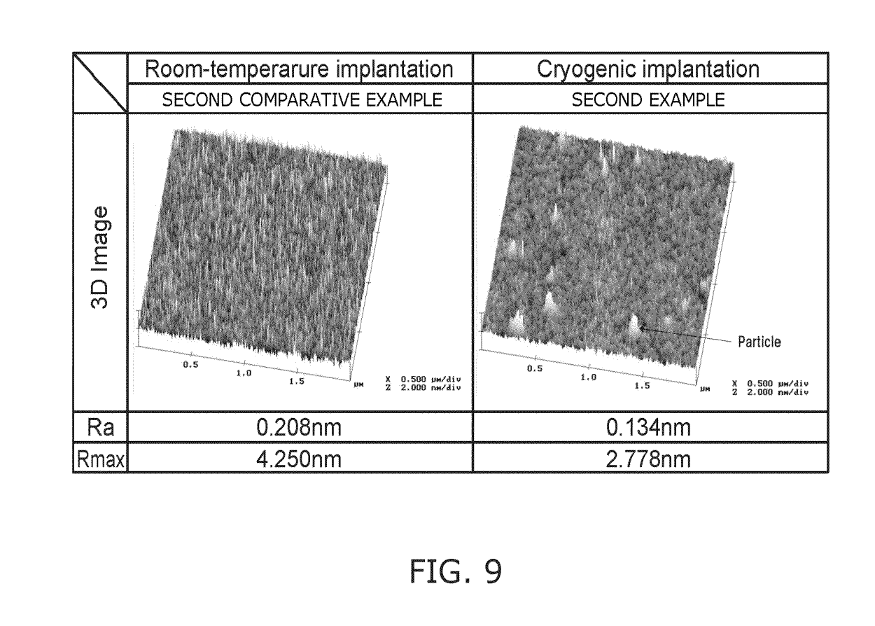

FIG. 9 is a figure showing the results of the measurements by AFM of the upper surface of the p-type impurity layer of the semiconductor device for the second comparative example and the second example.

In the AFM measurement results of the second comparative example and the second example as shown in FIG. 9, an irregular vertical interval having a difference between highs and lows of about 2 μm was confirmed for the second comparative example. On the other hand, for the second example, the irregular vertical interval had a difference between highs and lows of about 1 μm. Also, for the second comparative example, the surface average of roughness height was 0.208 nm; and the maximum roughness height was 4.250 nm. On the other hand, for the second example, the surface average of roughness height was 0.134 nm; and the roughness maximum height was 2.778 nm.

These results show that the roughness of the substrate surface after the ion implantation is improved by cooling the silicon substrate 101 when performing ion implantation.

Also, in this measurement, it was confirmed that an irregular vertical interval is not markedly observed in the case of boron implantation. In the case where arsenic which has an atomic radius larger than that of silicon (Si) is ion-implanted, an amorphous layer is formed in the substrate and interstitial defects and vacancy defects are formed inside the amorphous layer regardless of the substrate temperature. At this time, in the silicon substrate at the low temperature, although the mobility of the vacancies is low, the interstitial mobility is relatively high. Accordingly, although the vacancies move and clusters are formed easily in the silicon substrate at room temperature, the mobility of the vacancies is low and clusters are hard to be formed in the silicon substrate at low temperatures. Accordingly, it is suggested that a pronounced difference is observed in the formation of the irregular vertical interval for the second comparative example and the second example because the cluster formation of the vacancies promotes the formation of the irregular vertical interval.

Further, the relationship between the existence probability of the vacancies and the ion implantation temperature was verified. The point defect density distribution at each temperature was calculated by a KMC (Kinetic Monte Carlo) simulator; and the probability of the point defects recombining was verified from the occurrence amount of the vacancies and the interstitial defects and the mobility of the vacancies and the interstitial defects at that temperature. As a result, for ion implantation at room temperature (60° C.), the proportion of V-V combination in which two vacancies combine was dominant. That is, simulation results were obtained that the vacancies were not able to exist as single vacancies. Simulation results were obtained, in the case where ion implantation is performed at a substrate temperature of 0° C. to −100° C., that the formation probability of V0 (Natural-Vacancies) in which the vacancies exist as single vacancies increases as the temperature of the silicon substrate is reduced to low temperatures. Also, the formation probability of V0 reached substantially 100% when the temperature of the silicon substrate was −100° C. or less. Further, simulation results were obtained that the formation probability of V++ (Double-plus charged vacancies) in which the vacancies can exist stably as single vacancies even more than V0 increases in the case where the temperature of the silicon substrate was reduced when performing the ion implantation. Furthermore, the simulations illustrated that the existence probability of V++ exceeds 50% when the substrate temperature is −135° C., and the existence probability of V++ at −150° C. is about 90%.

Then, a semiconductor device was made as a third comparative example by performing ion implantation of arsenic into a region corresponding to the p-type channel layer 130 of the silicon substrate 101 at room temperature by setting the acceleration energy to 10 keV and the dose to 2×10¹⁴ cm⁻². Other than the temperature of the silicon substrate in the ion implantation and the ion implantation of arsenic being performed at the conditions described above, the configuration of the semiconductor device of the third comparative example is similar to that of the semiconductor device according to the embodiment.

Also, a semiconductor device was made as a fourth comparative example in which the ion implantation of arsenic was performed at the same conditions as the third comparative example by cooling to −100° C. at which the existence probability of V0 is dominant. Other than the temperature of the silicon substrate in the ion implantation and the ion implantation of arsenic being performed at the conditions described above, the configuration of the semiconductor device of the fourth comparative example is similar to that of the semiconductor device according to the embodiment.

Further, a semiconductor device was made as a third example in which cooling is performed to −150° C. at which the existence probability of V++ is dominant, the acceleration energy was set to 10 keV, and the dose was set to 2×10¹⁴ cm⁻² when performing the ion implantation of arsenic into a region corresponding to the p-type channel layer 130 of the silicon substrate 101. Other than the ion implantation of arsenic being at the conditions described above, the configuration of the semiconductor device of the third example is similar to that of the semiconductor device according to the embodiment.

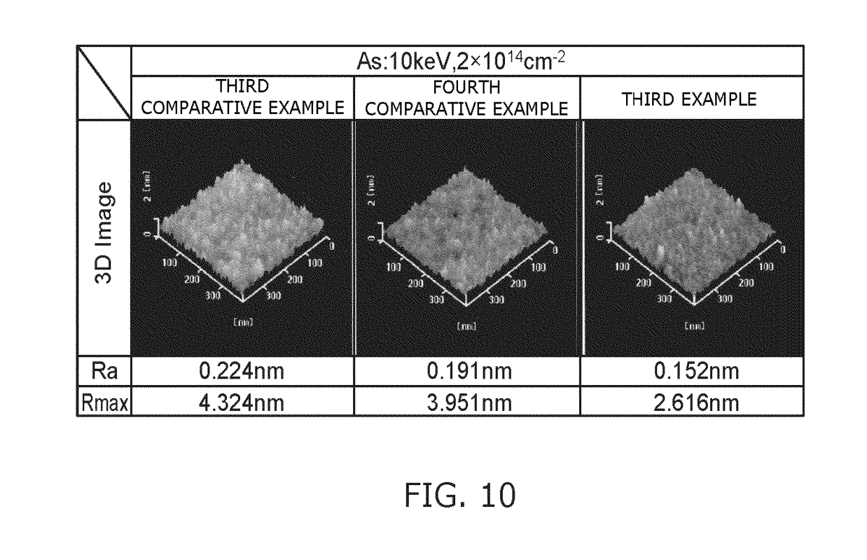

FIG. 10 is a figure showing the results of the measurements by AFM of the upper surface of the p-type impurity layer of the semiconductor device for the third comparative example, the fourth comparative example, and the third example.

From the measurement photographs of AFM as shown in FIG. 10, an irregular vertical interval having a difference between highs and lows of about 2 μm was confirmed for the third comparative example in which the ion implantation was performed at room temperature. Also, for the fourth comparative example in which the ion implantation was performed at −100° C., an irregular vertical interval having a difference between highs and lows of about 1.8 μm was confirmed; but compared to the third comparative example, the occurrence density was low. For the third example in which the ion implantation was performed at −150° C., the difference between highs and lows of the irregular vertical interval was 1.3 μm. Also, the occurrence density of the irregular vertical interval was low compared to the third comparative example and the fourth comparative example.

Also, the surface average of roughness height and the maximum roughness height of the measured front surface for the third comparative example were a surface average of roughness height of 0.224 nm and a maximum roughness height of 4.324 nm. For the fourth comparative example, surface average of roughness height was 0.191 nm; and the maximum roughness height was 3.951 nm. For the third example, surface average of roughness height was 0.152 nm; and the maximum height was 2.616 nm.

From these results, it was confirmed that the roughness improves due to the effects of the formation of the vacancy clusters suppressed by cooling the silicon substrate when performing the ion implantation. Also, because the effects of the improvement of the roughness obtained by cooling the silicon substrate arise most in the temperature range in which the existence probability of V++ is high, it is favorable to perform the ion implantation at a substrate temperature of −135° C. or less where the existence probability of V++ exceeds 50%.

Then, the amount of the occurrence of interface states at the interface between the p-type channel layer 130 and the gate insulator film 111 was verified for the semiconductor devices of the third comparative example and the third example.

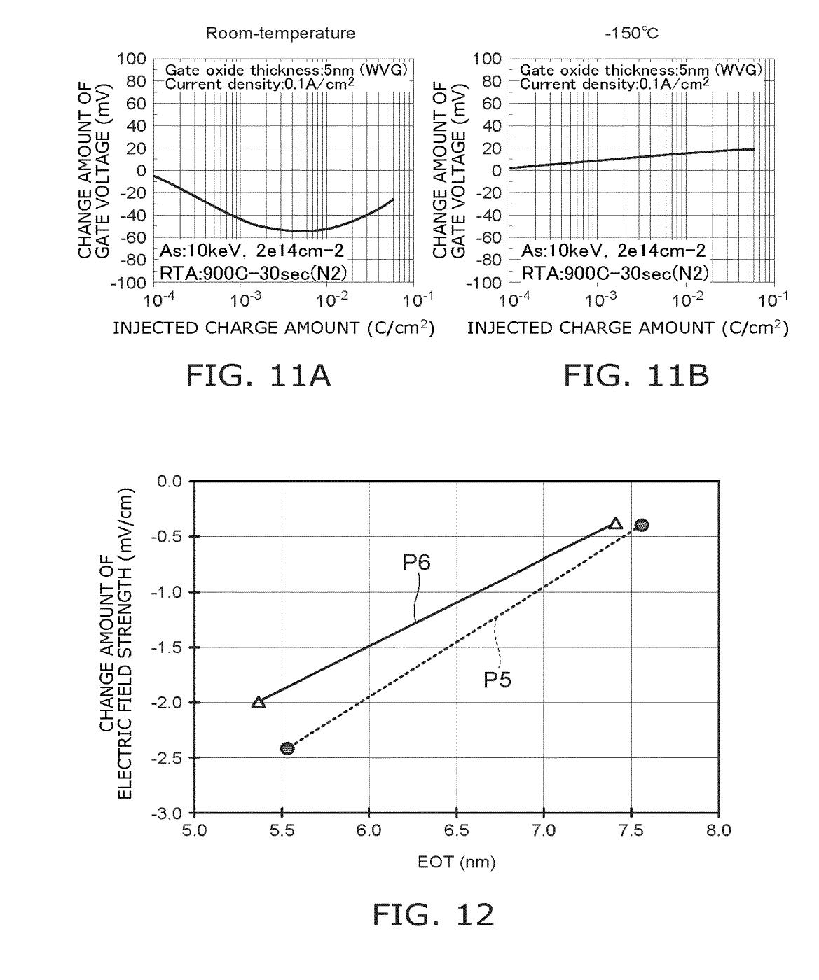

FIG. 11A and FIG. 11B are graphs showing the charge trap amount of the interface states, where the horizontal axis is the injected charge amount (C/cm²), and the vertical axis is the change amount (mV) of the gate voltage characteristics.

As shown in FIG. 11A and FIG. 11B, in the third comparative example, it is confirmed that although the change amount of the gate voltage at the initial injected charge shifts toward the negative voltage side, the change amount shifts toward the positive voltage side with increase of the amount of injected charge. On the other hand, in the case of the third example, reversal behavior from a negative voltage side to a positive voltage side such as that of the third comparative example was not confirmed. This result shows that in the case of the third comparative example, holes are trapped in the interface state excited by the stress application; the change amount of the gate voltage shifts to a negative voltage side; and due to electron traps occurring as the injected charge progresses, the change amount of the gate voltage shifts toward the positive voltage side; but in the case of the third example, it is shown that the hole traps do not occur; and the existence of vacancies or vacancy clusters is low.

Also, although the change amount of the gate voltage was about 60 mV for the third comparative example, the change amount was about 20 mV for the third example.

Accordingly, it was confirmed that the charge trap amount is lower for the semiconductor memory device of the third example than for the semiconductor device of the third comparative example.

Then, the relationship between the stress-induced leakage current and the electrical oxide film thickness (EOT) of the semiconductor devices was evaluated by CV (Cyclic Voltammetry) measurements. In the evaluations, semiconductor devices similar to the semiconductor devices of the first comparative example and the first example having surface areas of 100 μm² were used. The ion implantation of boron was performed by setting the acceleration energy to 10 keV and the dose to 1×10¹³ cm⁻². Also, in the measurements, the development of interface state density is accelerated by applying the stress for 5 seconds with the current density of 0.1 A/cm². In the CV measurements, constant current stress having a current density of 1×10⁻⁸ A/cm² was applied to the semiconductor devices.

FIG. 12 is a graph showing the hysteretic characteristics before and after the constant current stress, where the horizontal axis is the electrical oxide film thickness (nm), and the vertical axis is the change amount (mV/cm) of the electric field strength. The measurement data of the change amount of the electric field strength with respect to the EOT of the first comparative example is shown as measurement data P5; and the measurement data of the change amount of the electric field strength with respect to the EOT of the first example is shown as measurement data P6.

As shown in FIG. 12, a large difference between the measurement data P5 of the first comparative example and the measurement data P6 of the first example was not confirmed for the change amount of the electric field strength at an EOT of a film thickness of about 7.5 nm. However, comparing the slopes of the measurement data P5 of the first comparative example and the measurement data P6 of the first example, the slope of the measurement data P6 was smaller. Normally, the change amount of the electric field strength increases as the gate insulator film 111 is thinned. Compared to the first comparative example, the change amount of the electric field strength of the first example decreased as the value of the EOT became small. From this result, it can be confirmed that the occurrence of the stress-induced leakage current in the case where the EOT is thin can be suppressed in the first example.

According to the embodiments described above, a semiconductor device having improved electrical characteristics and a method for manufacturing the semiconductor device can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device, comprising:
an ion implantation process of performing ion implantation of an ion species including at least one type of atom of boron, antimony, arsenic, phosphorus, or indium into a semiconductor region at low temperature; and
an electrode formation process of forming a source region and a drain region at two mutually-separated locations on the semiconductor region and forming an electrode in a region directly above the semiconductor region between the source region and the drain region with an insulating film interposed between the electrode and the semiconductor region.

2. The method for manufacturing the semiconductor device according to claim 1, wherein the ion implantation of the ion implantation process is performed at a temperature of −135° C. or less.

3. The method for manufacturing the semiconductor device according to claim 1, wherein
the electrode formation process includes:
forming the insulating film on the semiconductor region;
forming the electrode on the insulating film; and
forming the source region and the drain region, and
a channel region is formed in the ion implantation process between the source region and the drain region.

4. The method for manufacturing the semiconductor device according to claim 3, wherein the forming of the insulating film includes a process of thermal oxidation of the semiconductor region.

5. The method for manufacturing the semiconductor device according to claim 1, wherein
the electrode formation process includes:
forming the insulating film on the semiconductor region;
forming the electrode on the insulating film; and
forming a channel region in a region directly under the electrode, and
the source region and the drain region are formed by the ion implantation process.

6. The method for manufacturing the semiconductor device according to claim 1, wherein
the electrode formation process includes:
forming the insulating film on the semiconductor region;
forming the electrode on the insulating film;
forming the source region and the drain region; and
forming a channel region in a region directly under the electrode, and
an extension layer is formed between the source region and the channel region, and between drain region and the channel region by the ion implantation process.

7. A method for manufacturing a semiconductor device, comprising:
performing ion implantation of an ion species including at least one type of atom of boron, antimony, arsenic, phosphorus, or indium into a semiconductor region at low temperature;
forming a source region and a drain region at two mutually-separated locations on the semiconductor region;
forming a first insulating film in a region directly above the semiconductor region between the source region and the drain region;
performing the ion implantation for the semiconductor region through the first insulating film at low temperature;
removing the first insulating film;
forming a second insulating film on the semiconductor region where the first insulating film has been removed; and
forming an electrode on the second insulating film.

8. The method for manufacturing the semiconductor device according to claim 7, further comprising:
forming a dummy gate electrode in a region directly above the semiconductor region before forming the source region and the drain region; and
removing the dummy gate electrode after forming the source region and the drain region at two mutually-separated locations on the semiconductor region, and
the source region and the drain region being formed by an ion implantation process using the dummy gate as a mask.

9. The method for manufacturing the semiconductor device according to claim 7, wherein the ion implantation of the ion implantation process is performed at a temperature of −135° C. or less.

10. The method for manufacturing the semiconductor device according to claim 7, further comprising:
forming a dummy gate on the semiconductor region;
forming two extension regions by using the dummy gate as a mask; and
forming a third insulation films on side surfaces of the dummy gate;
removing the dummy gate electrode after forming the source region and the drain region at two mutually-separated locations on the semiconductor region, and
the source region and the drain region being formed by an ion implantation process using the dummy gate and the third insulation films as a mask.

11. A semiconductor device, comprising:
a semiconductor region;
an insulating film provided on the semiconductor region;
a source region and a drain region provided in the semiconductor region to be separated from each other;
a gate electrode provided on a region directly above the semiconductor region between the source region and the drain region; and
a surface average of roughness height of a surface of the semiconductor region between the source region and the drain region being not more than 0.2 nm, and a maximum difference between highs and lows of the interface being not more than 2 nm.

12. The semiconductor device according to claim 11, wherein the insulating film thickness is 8 nm or less.

13. The semiconductor device according to claim 11, wherein the semiconductor region includes silicon, and the insulating film includes silicon oxide.

14. The semiconductor device according to claim 11, further comprising a channel region provided between the source region and the drain region in a region of the semiconductor region directly under the gate electrode.

15. The semiconductor device according to claim 14, wherein
the gate electrode is on the insulating film, and
the surface is a surface of the channel region directly under the insulating film.

16. The semiconductor device according to claim 15, wherein a part of the channel region including the surface has at least one type of atom of boron, antimony, arsenic, phosphorus, or indium.

17. The semiconductor device according to claim 11, wherein the surface is a surface of the source region directly under the insulating film, and a surface of the drain region directly under the insulating film.

18. The semiconductor device according to claim 17, wherein
a part of the source region including the surface has at least one type of atom of boron, antimony, arsenic, phosphorus, or indium; and
a part of the drain region including the surface has at least one type of atom of boron, antimony, arsenic, phosphorus, or indium.

19. The semiconductor device according to claim 14, further comprising an extension region between the source region and the channel region, and between the drain region and the channel region,
the surface being a surface of the extension region directly under the insulating film.

20. The semiconductor device according to claim 19, wherein a part of the extension region including the surface has at least one type of atom of boron, antimony, arsenic, phosphorus, or indium.
